(19) United States
(12) Patent Application Publication
(10) Pub. No.: US 2007/0141257 A1
(43) Pub. Date: Jun. 21, 2007

(54) Method and apparatus for forming metal silicate film, and method for manufacturing semiconductor device

(75) Inventors: Tsuyoshi Takahashi, Yamanashi (JP); Shintaro Aoyama, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minato-ku, Tokyo-to (JP)

(21) Appl. No.: 10/593,254

(22) PCT Filed: Mar. 30, 2005
(86) PCT No.: PCT/JP05/06158

§ 371 Date: Sep. 18, 2006

(30) Foreign Application Priority Data
Mar. 31, 2004 (JP) 2004-105300

(51) Int. Cl. C23C 16/00; C23C 16/40; H01L 21/31

(52) U.S. Cl. 427/255.31; 427/255.37; 118/725; 438/758

(57) ABSTRACT

An HTB gas and a disilane gas are introduced into a process chamber (1), and a hafnium silicate film is formed on a silicon substrate (W) by CVD. The film is formed while controlling the substrate temperature by a heater (5) embedded in a susceptor (2) supporting the substrate. The substrate temperature during film formation is controlled not less than the temperature at which HTB is decomposed into hafnium hydroxide and isobutylene and less than the autolysis temperature of the disilane gas, preferably not less than 350° C. and not more than 450° C.

### FIELD OF THE INVENTION

The present invention relates to a method and an apparatus for forming a metal silicate film, e.g., a hafnium silicate film or the like, and a method for manufacturing a semiconductor device having a metal silicate film as a gate insulating film.

### BACKGROUND OF THE INVENTION

To meet a recent trend of high integration and speed-up of an LSI, a finer design rule is required for a semiconductor device in the LSI. Accordingly, a gate insulating film of a CMOS device is required to have a SiO₂ capacitance equivalent film thickness, which is an equivalent oxide thickness (EOT), smaller than about 1.5 nm. Materials of high dielectric constant that are also known as “high-k materials” are attracting attention as materials for realizing such thin EOT insulating film without increasing a gate leak current.

To be used for the gate insulating film, the high-k dielectric material is required not to interdiffuse with a silicon substrate and needs to be stable thermodynamically. From such a point of view, oxides of hafnium, zirconium and lanthanide elements or silicates thereof are considered as promising materials.

Recently, CMOS logic devices of metal silicate films such as a hafnium silicate (HfSiOₓ) film or a zirconium silicate (ZrSiOₓ) film have been extensively evaluated, and are expected to be materialized as highly promising candidates for a next-generation gate insulating film thanks to their high carrier mobility.

As for a conventional method of forming a metal silicate film by a CVD (chemical vapor deposition) method, there is known a method using, as source materials, a metal alkoxide source together with a silicon source such as a TEOS (tetraethoxysilane) compound or a siloxane compound (see, for example, Japanese Patent Laid-open Application Nos. 2002-343790 and 2003-82464).

Further, there is known another method using, as a silicon source, an inorganic compound such as a silicon hydride or the like. For example, a method of forming a hafnium silicate film by using as source materials hafnium tetra-tertiary butoxide (HTB) and disilane (Si₂H₆) in a vertical batch furnace is disclosed by Semiconductor Leading Edge Technologies Inc (Aoyama et al., International Workshop on Gate Insulator 2003, Nov. 7, 2003).

In case of using the vertical batch furnace, when a temperature around a gas inlet opening increases, the source gases are activated, and thus the gas inlet opening may be clogged by a deposition of oxides thereof. To this end, a hafnium silicate film is formed at a comparatively low temperature of about 280° C.

However, when the film is formed at such a low temperature, the HTB used as a hafnium source is decomposed insufficiently. Then, the undecomposed materials containing a large amount of carbon can infiltrate into the film to affect film characteristics such that a high quality of insulation thereof may not be secured.

To solve such problems, conventionally, the metal silicate film is formed and then subjected to a quality modification process by being exposed to oxygen radicals or ozone to reduce a carbon concentration in the film. However, a silicon substrate underlying the metal silicate film is oxidized in the quality modification process to increase the equivalent oxide thickness (EOT) of the gate insulating film, thereby causing another problem.

### SUMMARY OF THE INVENTION

It is, therefore, an object of the present invention to provide a method and an apparatus capable of forming a high-quality metal silicate film. Further, it is another object of the present invention to provide a method of manufacturing a semiconductor device having a high-quality metal silicate film as a gate insulating film.

The inventors have studied over this matter to solve the above-described problems, and have found the following.

First, the inventors have found that, when forming a metal silicate film by employing a CVD process using a metal alkoxide gas and a silicon hydride gas, if the temperature is higher than a temperature level at which metal alkoxide is decomposed into metal hydroxide and a specific intermediate, it becomes difficult for carbide originated from the source material to remain in the film, thereby enhancing the insulation property. However, if the temperature is excessively increased to facilitate this reaction, self-decomposition of silicon hydride occurs to form silicon-silicon bonds, thereby deteriorating the insulation property and increasing the surface roughness of the film. Further, the inventors also have found that, when forming a hafnium silicate film by using a CVD process using HTB and disilane as a metal alkoxide gas and silicon hydride, respectively, if the temperature ranges between 350° C. and 450° C., there occurs HTB decomposition in a desired manner, and the self-decomposition of disilane does not take place.

The present invention was achieved based on the above findings. Hence, in accordance with one aspect of the invention, there is provided a film forming method comprising the steps of preparing a substrate; and forming a metal silicate film on the substrate by a CVD process using a gas of metal alkoxide and a gas of silicon hydride, wherein the step of forming the film is performed by setting a substrate temperature to be higher than or equal to a temperature at which the metal alkoxide is decomposed into metal hydroxide and a specific intermediate, and lower than a self-decomposition temperature of the silicon hydride.

More specifically, in accordance with the same aspect of the invention, there is provided a film forming method comprising the steps of preparing a substrate; and forming a hafnium silicate film on the substrate by a CVD process using a HTB gas and a disilane gas, wherein the step of forming the film is performed by setting a substrate temperature to be higher than or equal to 350° C. and lower than or equal to 450° C.

In accordance with a second aspect of the invention, there is provided a film forming apparatus for forming a metal silicate film on a substrate by a CVD process using a gas of metal alkoxide and a gas of silicon hydride, the apparatus comprising a process chamber for accommodating therein a substrate; a heater for heating the substrate in the process chamber; a gas supply system having a vaporizing unit for vaporizing metal alkoxide source material into a gas of metal alkoxide, the gas supply system for separately supplying the gas of the metal alkoxide and the gas of the silicon hydride to the process chamber; a shower head for diffusing the gas of metal alkoxide and the gas of silicon hydride, each being supplied from the gas supply system, into the process chamber; and a controller for controlling the heater such that the substrate temperature in the process chamber in the step of forming the film is set to be higher than or equal to a temperature at which the metal alkoxide is decomposed into metal hydroxide and a specific intermediate and lower than a self-decomposition temperature of the silicon hydride.

More specifically, in accordance with the same aspect of the invention, there is provided a film forming apparatus for forming a hafnium silicate film on a substrate by a CVD process using an HTB gas and a disilane gas, comprising a process chamber for accommodating therein a substrate; a heater for heating the substrate in the process chamber; a gas supply system having a vaporizing unit for vaporizing an HTB liquid into an HTB gas, the gas supply system separately supplying the HTB gas and the disilane gas to the process chamber; a shower head for diffusing the HTB gas and the disilane gas, each being supplied from the gas supply system, into the process chamber; and a controller for controlling the heater such that the substrate temperature in the process chamber in the step of forming the film is set to be higher than or equal to 350° C. and lower than or equal to 450° C.

In accordance with a third aspect of the invention, there is provided a method for manufacturing a semiconductor device, comprising the steps of preparing a silicon substrate; forming a silicon oxide film functioning as a base insulating film on the silicon substrate; forming a metal silicate film functioning as a gate insulating film on the silicon oxide film by a CVD process using a gas of metal alkoxide and a gas of silicon hydride; and forming a gate electrode on the metal silicate film, wherein the step of forming the metal silicate film is performed by setting a substrate temperature to be higher than or equal to a temperature at which the metal alkoxide is decomposed into metal hydroxide and a specific intermediate and lower than a self-decomposition temperature of the silicon hydride.

In accordance with the present invention, when forming a metal silicate film on a substrate by a CVD process using a gas of metal alkoxide such as HTB and a gas of silicon hydride such as disilane, the substrate temperature during the film formation is set to higher than or equal to a temperature level at which the metal alkoxide gas is decomposed into metal hydroxide and a specific intermediate and lower than a self-decomposition temperature of the silicon hydride gas. Therefore, it is difficult for carbon to remain in the metal silicate film, and the silicon-silicon bonds are not easily formed in the same film. In this manner, it is possible to form a high-quality metal silicate film having a good insulation property and a small surface roughness.

### BRIEF DESCRIPTION OF THE DRAWINGS

FIG. 1 is a cross sectional view of a film forming apparatus in accordance with a first preferred embodiment of the present invention.

FIG. 2 shows infrared absorption spectra illustrating thermal decomposition characteristics of HTB.

FIG. 3 depicts variations in a thickness of an HfO₂ film on a wafer at different wafer temperatures.

FIG. 4 provides SEM pictures showing film surface conditions at various wafer temperatures.

FIG. 5 illustrates concentration distributions of respective atoms in a direction of a film thickness in case of forming a hafnium silicate film at a wafer temperature of 360° C. by using the apparatus of FIG. 1.

FIG. 6 describes concentration distributions of carbon in the direction of the film thickness in case of forming the hafnium silicate film at a wafer temperature of 280° C. by using a conventional vertical batch furnace.

FIGS. 7A to 7C show XPS spectra of the hafnium silicate film formed in cases of setting the substrate temperatures to (a) 360° C., (b) 495° C. and (c) 542° C., respectively.

FIGS. 8A to 8E depict variations in a composition of the hafnium silicate film varying with a disilane gas flow rate in cases of setting the substrate temperature to (a) 360° C., (b) 405° C., (c) 450° C., (d) 495° C. and (e) 542° C., respectively.

FIG. 9 illustrates surface roughnesses of the hafnium silicate film formed on the wafer in cases of differently setting the wafer temperatures and the disilane gas flow rate.

### DETAILED DESCRIPTION OF THE PREFERRED EMBODIMENT

Hereinafter, preferred embodiments of the present invention will be described in detail with reference to the accompanying drawings.

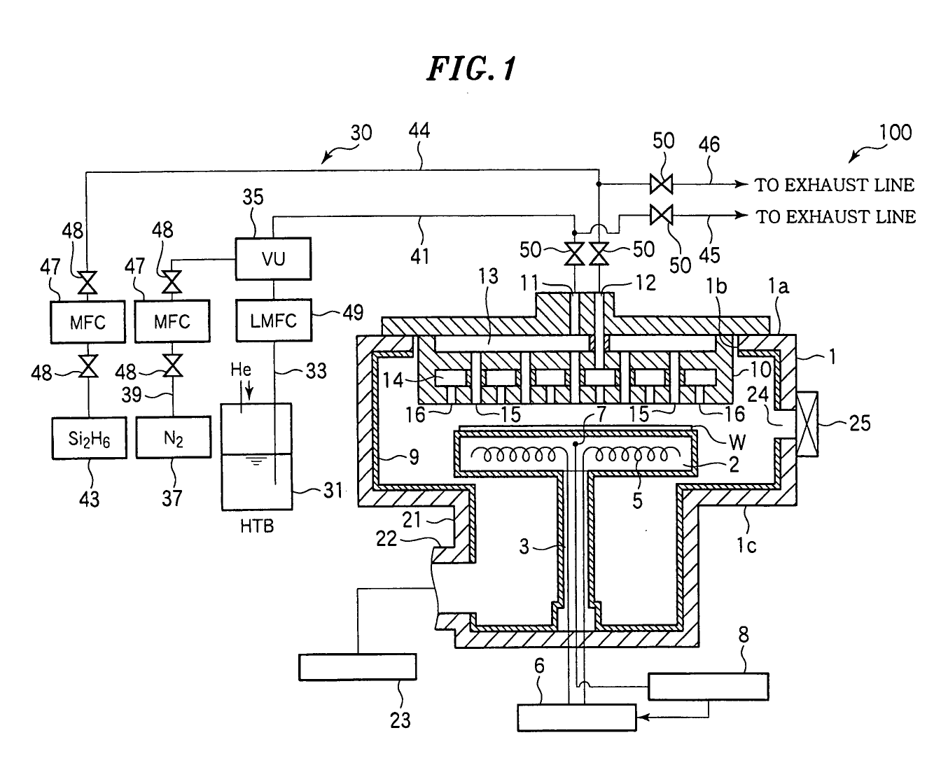

FIG. 1 is a cross sectional view of a film forming apparatus in accordance with a first preferred embodiment of the present invention. A film forming apparatus 100 has an approximately cylindrical process chamber 1 configured to be airtight. Provided in the process chamber 1 is a susceptor 2 for supporting a Si substrate (wafer) W serving as an object to be processed, the susceptor 2 being made of ceramic such as AlN or the like. The susceptor 2 is supported by a cylindrical supporting member 3. Further, a heater 5 is buried in the susceptor 2 and is connected to a heater power supply 6. Meanwhile, a thermocouple 7 is provided near a top surface of the susceptor 2 and is configured to send a signal to a controller 8. The controller 8 transmits a command to the heater power supply 6 in response to the signal sent from the thermocouple 7 and also controls a temperature of the Si wafer. W by controlling a heating performance of the heater 5.

Further, quartz liners 9 are provided on inner walls of the process chamber 1 as well as on outside surfaces of the susceptor 2 and the supporting member 3 to prevent deposits from being deposited thereon. Also, a purge gas (shield gas) is allowed to flow between the quartz liners 9 and wall portions of the process chamber 1, thereby preventing the deposits from being deposited on the wall thereof to prevent a contamination thereof.

Formed on a ceiling wall 1a of the process chamber 1 is a circular opening 1b, in which a shower head 10 protruding into the process chamber 1 is inserted. The shower head 10 serves to diffuse into the process chamber 1 a film forming gas supplied from a gas supply system 30 to be described later. At an upper portion of the shower head 10 are formed a first introduction path 11 for introducing an HTB gas as a metal source gas and a second introduction path 12 for introducing a disilane gas as a silicon hydride gas. An upper and a lower space 13 and 14, each having a horizontal disk shape, are formed inside the shower head 10. The first introducing path 11 leads to the upper space 13, and a first gas discharge path 15 extends from the upper space 13 to a bottom surface of the shower head 10. The second introduction path 12 leads to the lower space 14, and a second gas discharge path 16 extends from the lower space 14 to the bottom surface of the shower head 10. In other words, the shower head 10 is of a post-mix type, in which the HTB gas introduced from the first introduction path 11 and the disilane gas introduced from the second introduction gas 12 are respectively discharged through the gas discharge paths 15 and 16 without being mixed with each other.

A gas exhaust vessel 21 protruding downward is connected to a bottom wall 1c of the process chamber 1. Coupled to a side surface of the gas exhaust vessel 21 is a gas exhaust line 22, which in turn is connected to a gas exhaust system 23. Further, by operating the gas exhaust system 23, an inner space of the process chamber 1 can be depressurized to a predetermined vacuum level. Installed on a sidewall of the process chamber 1 are a loading/unloading port 24 for loading and unloading the wafer W between a wafer transfer chamber (not shown) and the process chamber 1, and a gate valve 25 for opening and closing the loading/unloading port 24.

The gas supply system 30 includes an HTB tank 31 for storing therein HTB liquid; a N₂ gas supply source 37 for supplying a N₂ gas as a carrier gas; and a disilane gas supply source 43 for supplying a disilane gas. Further, the gas supply system 30 has a vaporizing unit for vaporizing the HTB liquid into an HTB gas (HTB steam).

By introducing a force-feed gas such as a He gas into the HTB tank 31, the HTB liquid in the tank 31 is guided to the vaporizing unit 35 via a conduit 33. A N₂ gas is supplied from the N₂ gas supply source 37 into the vaporizing unit 35 via a conduit 39. Due to the introduction of the N₂ gas, the HTB gas vaporized in the vaporizing unit 35 is transferred to the first introduction path 11 of the shower head 10 via a conduit 41. Further, the conduit 41 and the shower head 10 are provided with heaters that are not shown, so that they can be heated to a temperature at which the self-decomposition of the HTB gas does not yet take place.

The disilane gas supply source 43 is connected to a conduit 44. The disilane gas is transferred from the disilane gas supply source 43 to the second introduction path 12 of the shower head 10 via the conduit 44.

In each of the conduits 39 and 44 for transferring gases are installed two valves 48 and a mass flow controller (MFC) 47 positioned between the two of the valves 48. Further, pre-flow lines 45 and 46 are branched from the conduits 41 and 44, respectively. Further, valves 50 are installed at vicinities of the shower head 10 of the conduits 41 and 44 and also near branchpoints of the pre-flow lines 45 and 46. Moreover, a liquid mass flow controller (LMFC) 49 is installed in the conduit 33 for transferring liquid.

In the film forming apparatus configured as described above, a hafnium silicate film is formed on the Si wafer W as following.

First, an inner space of a process chamber 31 is evacuated to a pressure of about 400 Pa, and the Si wafer W is heated to a predetermined temperature by the heater 5.

In such state, the HTB liquid supplied from the HTB tank 31 is vaporized by the vaporizing unit 35 and then made to flow in the pre-flow line 45, and the disilane gas supplied from the disilane gas supply source 43 is made to flow in the pre-flow line 46, thereby performing a pre-flow for a specific period of time. Next, by switching the valve 50, the HTB gas (HTB steam) and the disilane gas are supplied to the first and the second introduction path 11 and 12, respectively, and then discharged into the process chamber 1 through the first and the second discharge path 15 and 16, respectively, thereby initiating the film formation. Herein, the conduit 41 and the shower head 10 are heated by the heaters that are not shown to a temperature at which the HTB are maintained in the vaporized state but the self-decomposition thereof does not yet take place. Thereafter, the HTB gas reacts with the disilane gas on the heated Si wafer W in the process chamber 1, forming a hafnium silicate film on the wafer W.

A molecular structure of HTB is shown in the following chemical formula. To be specific, an Hf atom in the center of the molecule is bonded to four O atoms, each of which bonded to a tertiary butyl group. Since an HTB molecule contains oxygen atoms, the hafnium silicate film can be formed by the reaction between the HTB gas and the disilane gas without using an oxidizing agent.

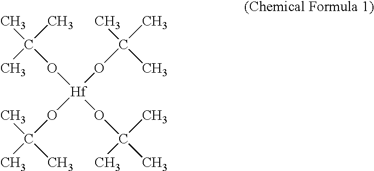

Herein, flow rates of the HTB, the N₂ gas and the disilane gas are set to be, for example, 0.2 to 1 L/min, 0.5 to 2 L/min and about 40 mL/min, respectively. Further, a pressure in the process chamber 1 during the film formation is set between 40 Pa and 400 Pa, for example.

Furthermore, a film forming temperature, i.e., a wafer temperature, needs to be determined by considering thermal decomposition characteristics of HTB and the disilane gas.

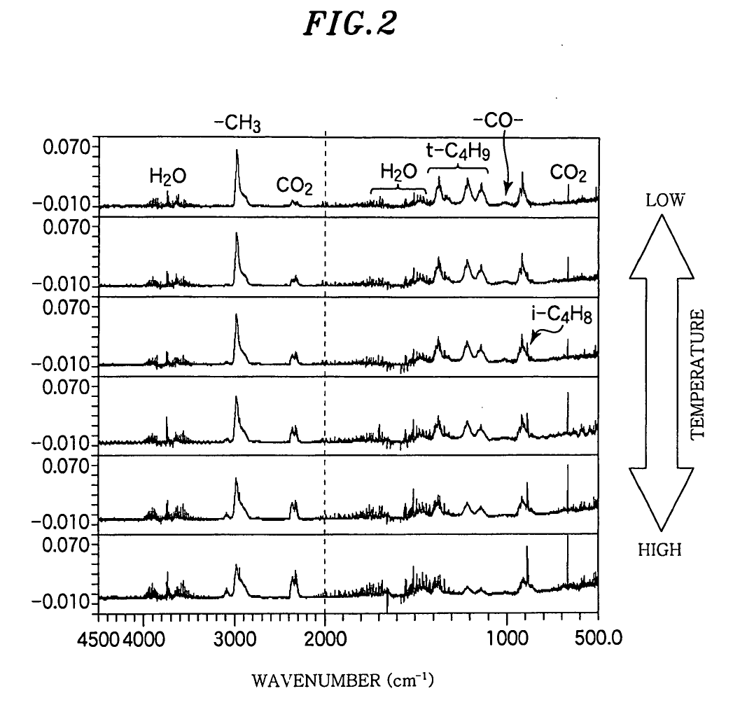

First, the thermal decomposition characteristics of HTB will be described. FIG. 2 shows infrared absorption spectra illustrating the thermal decomposition characteristics of HTB. As shown therein, when the film forming temperature is low, a large number of tertiary butyl groups (t-C₄H₉) are generated. Since t-C₄H₉ is difficult to be vaporized due to a large amount of carbon contained therein, it may become carbon impurities in the film to thereby detrimentally affect the film characteristics. On the other hand, as the film forming temperature increases, the number of the tertiary butyl groups are gradually reduced, and isobutylene is increased. This is considered to be caused by the fact that HTB is decomposed into hafnium hydroxide and isobutylene by the following chemical reaction.

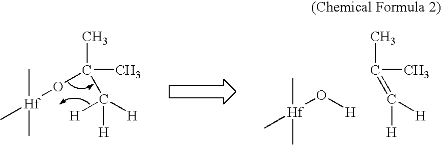

If the reaction for forming hafnium hydroxide becomes dominant, a generation amount of HfO2 increases, thereby forming a hafnium silicate film in which an amount of carbon impurities is small.

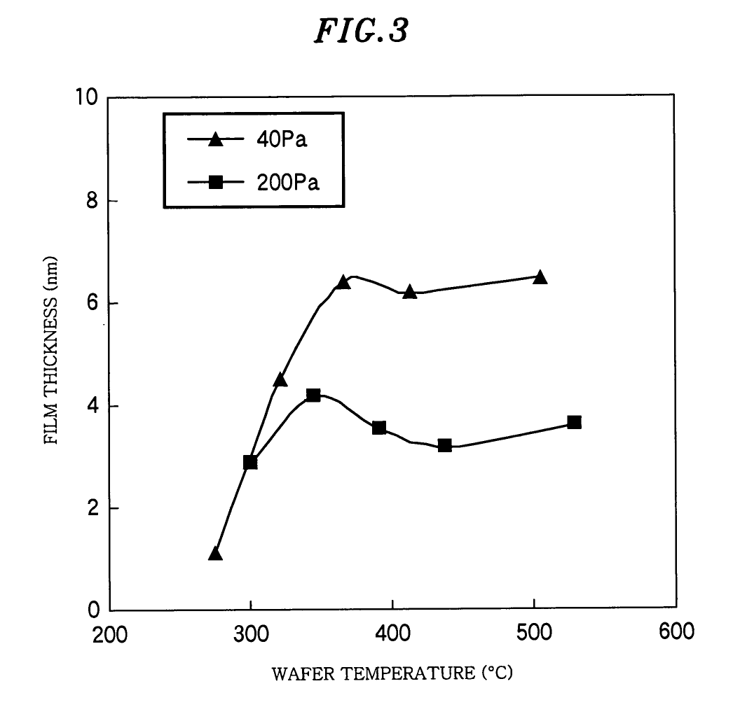

FIG. 3 depicts the variations in the thickness of the HfO₂ film formed on the wafer by supplying the HTB gas for 300 seconds while changing the wafer temperature. Herein, the pressure was set to be 40 Pa and 200 Pa. As illustrated therein, the thickness of the HfO₂ film increased until the wafer temperature (film forming temperature) increased to near 350° C., but the increase was saturated at a higher temperature. From this, it is deduced that, by forming the film at a temperature higher than or equal to 350° C., the aforementioned reaction occurred sufficiently, thereby reducing the carbon impurities in the film.

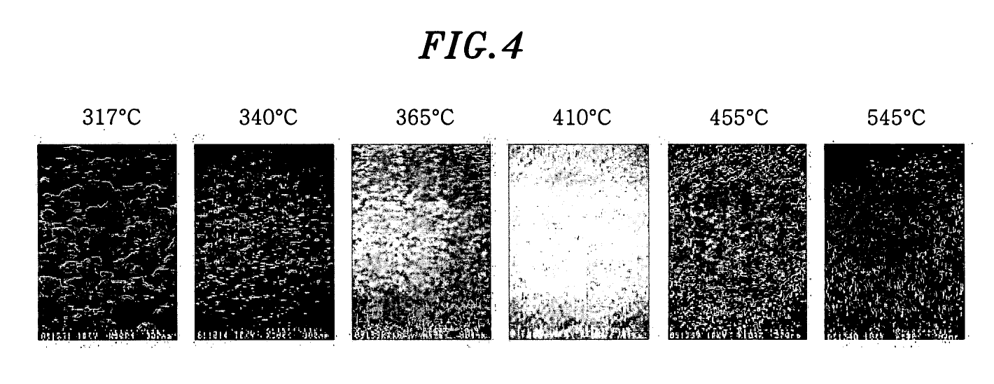

Further, FIG. 4 provides SEM pictures showing film surface conditions in case of supplying the HTB gas on a wafer where a SiO₂ film was attached for 300 seconds at various temperatures. As shown therein, it can be observed that the surface roughness decreased when the temperature ex ceeded 350° C. From this, it was verified that, by the aforementioned reaction, the amount of carbon impurities in the film and the surface roughness thereof were reduced.

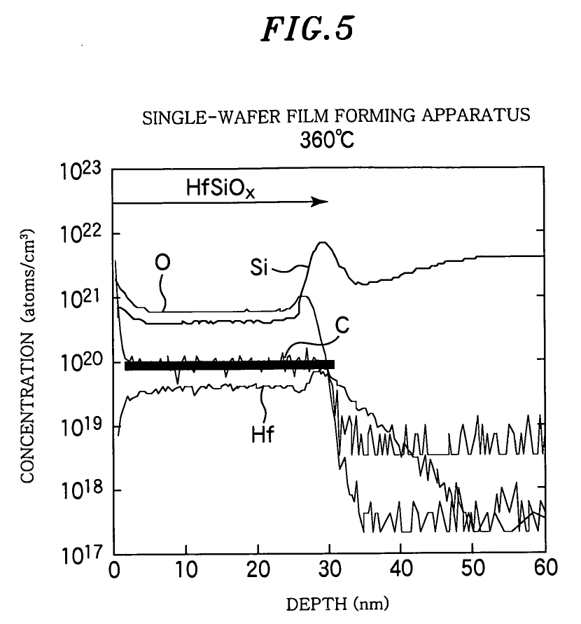

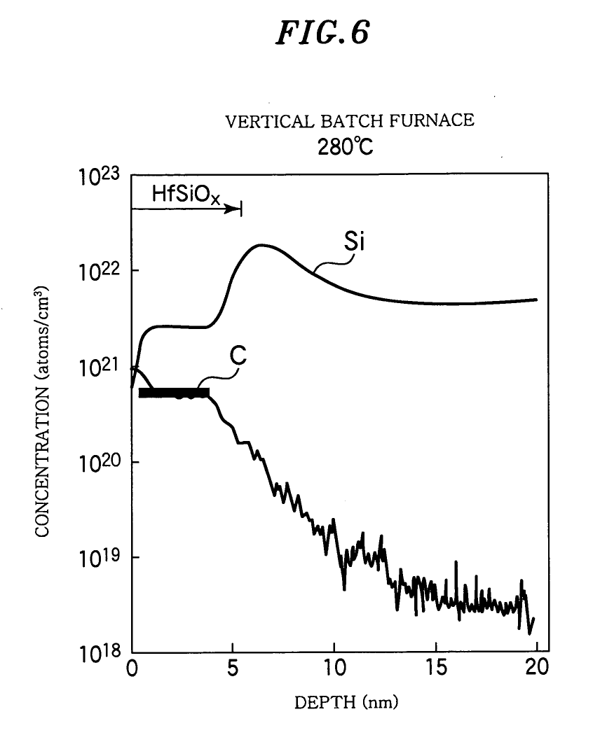

FIG. 5 illustrates concentration distributions of respective atoms in a direction of the film thickness in case of forming a hafnium silicate film at a wafer temperature of 360° C. by using the apparatus of FIG. 1, and FIG. 6 describes concentration distributions of carbon in the direction of the film thickness in case of forming a hafnium silicate film at the furnace body temperature, i.e., the wafer temperature, of 280° C. by using a conventional vertical batch furnace. As can be seen therefrom, when the hafnium silicate film was formed at 280° C. by using the conventional vertical batch furnace, the carbon concentration measured immediately after the film formation was about 5×10²⁰ atoms/cm³. On the other hand, it was verified that, when the hafnium silicate film was formed at 360° C. by using the apparatus of FIG. 1, the carbon concentration measured immediately after the film formation was about 1×10²⁰ atoms/cm³, i.e., one-fifth of the carbon concentration measured in case of using the conventional apparatus at 280° C.

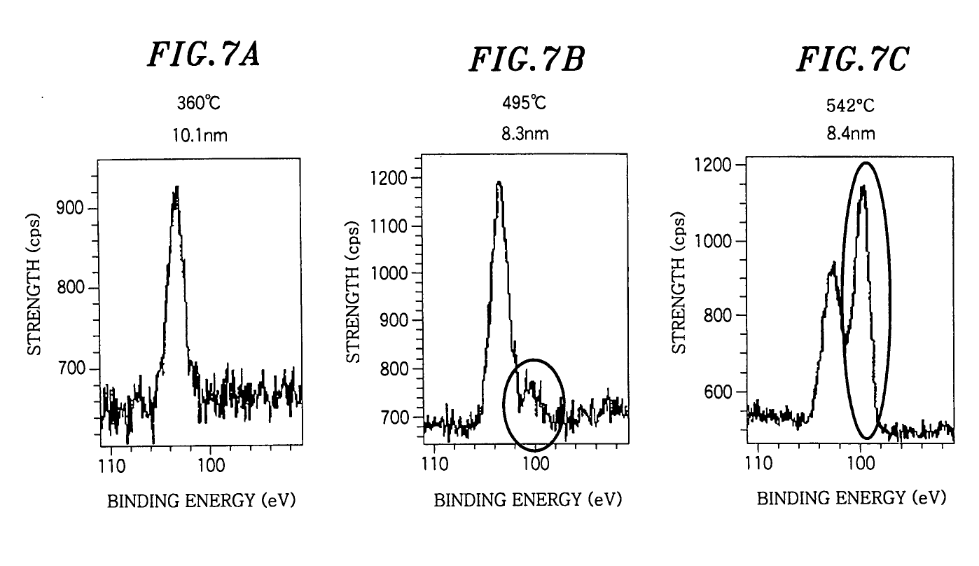

In the following, the decomposition characteristics of the disilane gas will be described. FIG. 7 shows XPS spectra (whose detection angle is 15°) of hafnium silicate films formed by setting the flow rate of the disilane gas to be 40 mL/min and the substrate temperature to be (a) 360° C., (b) 495° C. and (c) 542° C. Herein, the film thickness measured under the above conditions was 10.1 nm, 8.3 nm and 8.4 nm, respectively. As illustrated therein, in case of 495° C., a peak was observed near 100 eV, corresponding to the Si—Si bond, and this peak became outstanding in case of 542° C. However, such peak was not observed in case of 360° C. From this, it was verified that the Si—Si bonds were formed in the film at a temperature higher than or equal to 495° C.

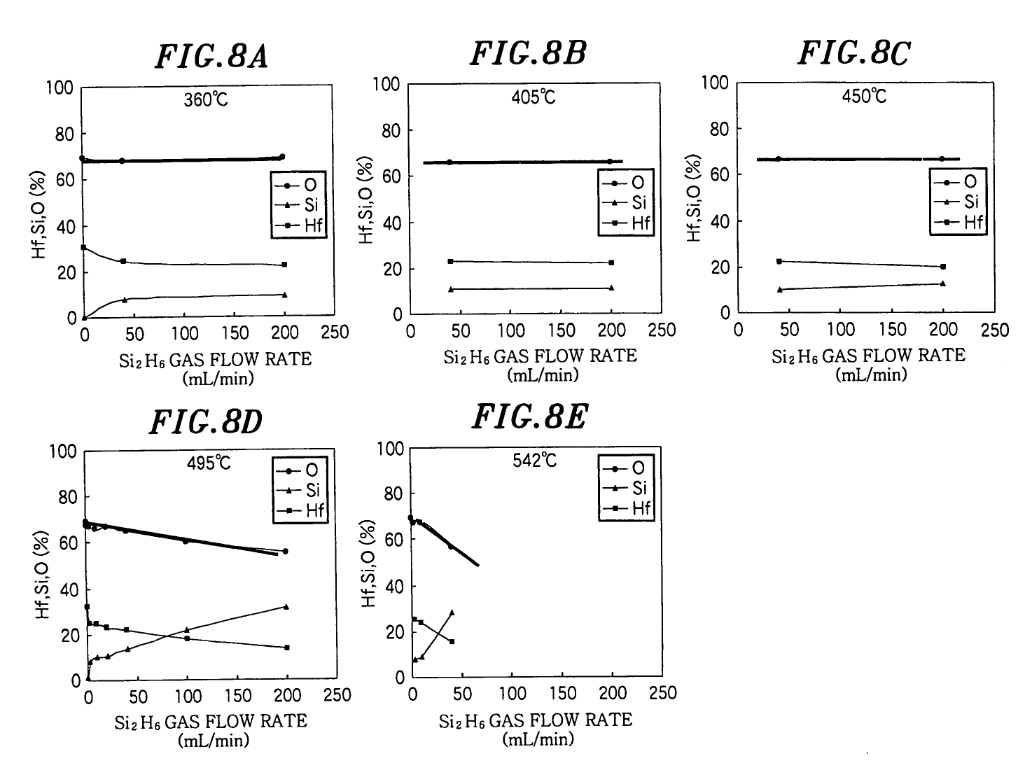

FIGS. 8A to 8E depict variations in the composition of the hafnium silicate film obtained by varying with the disilane gas flow rate in cases of setting the substrate temperature to (a) 360° C., (b) 405° C., (c) 450° C., (d) 495° C. and (e) 542° C., respectively. As can be seen therefrom, when the temperature was over 495° C., as the disilane gas flow rate increased, a ratio of oxygen decreased. However, such phenomenon was not observed when the temperature was lower than or equal to 450° C. Accordingly, it was deduced that the Si—Si bonds were formed in the film at 495° C. or higher.

This Si—Si bonds indicate that the self-decomposition of disilane took place. As the si—si bonds caused by the self-decomposition of disilane increased in number, the insulation property of the hafnium silicate film got deteriorated. From the above result, it was verified that a preferable film forming substrate temperature was not higher than 450° C., at which the self-decomposition of disilane did not take place.

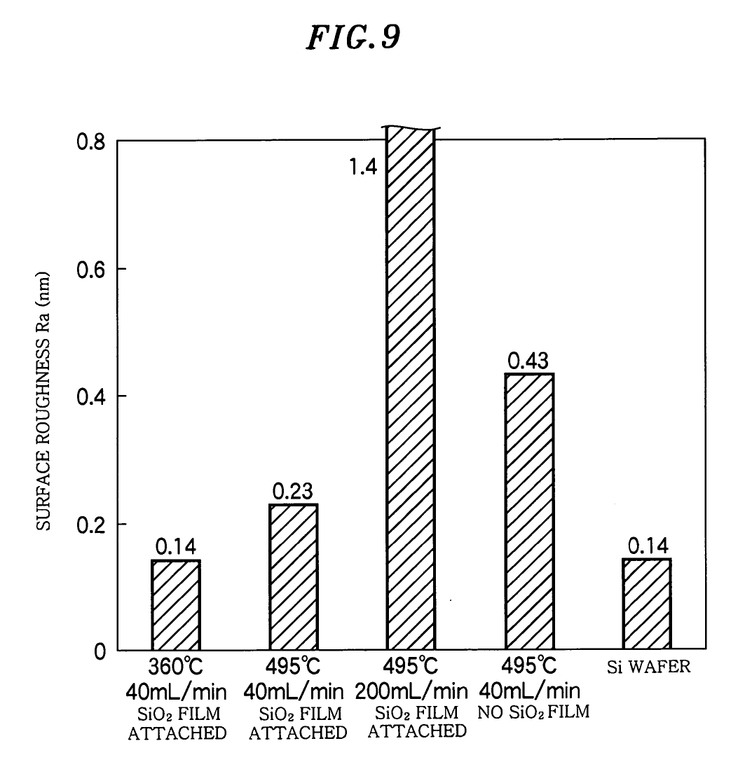

FIG. 9 illustrates the surface roughness (average roughness Ra) of the hafnium silicate film formed on a wafer where an ultra thin SiO₂ film was attached. Also shown therein for comparison are the surface roughness of the hafnium silicate film formed immediately on the wafer (under the conditions of the temperature of 495° C., the flow rate of 40 mL/min) and the surface roughness of the wafer itself. Herein, the film forming pressure was 40 Pa. Further, the ultra thin SiO₂ film on the wafer was assumed to be a base insulating film (interface layer) of an actual gate insulating film, and formed by oxidizing the silicon substrate with UV-excited oxygen radicals, to which a post-nitridation process was applied by using N2 radicals. As illustrated in FIG. 9, in case of the substrate temperature being 360° C. at which the self-decomposition reaction of disilane was not observed, a very favorable surface roughness Ra of 0.14 nm was obtained at the flow rate of 40 mL/min, which was equivalent to the surface roughness of the Si wafer. On the other hand, in case of the substrate temperature being 495° C. at which the self-decomposition reaction of disilane was observed, an increased surface roughness Ra of 0.23 nm was obtained at the same flow rate of 40 mL/min. Further, by increasing the flow rate to 200 mL/min, a notable surface roughness Ra of 1.4 nm was obtained. It was verified therefrom that, by suppressing the self-decomposition reaction of disilane, the surface roughness of the hafnium silicate film was improved. Further, when the hafnium silicate film was formed immediately on the wafer, a surface roughness Ra was measured to be 0.43 nm, which was greater than that of the wafer onto which the ultra thin SiO₂ film was attached.

Hence, when forming the hafnium silicate film by using the HTB and the disilane gas in accordance with the present embodiment, the substrate temperature during the film formation is set to be higher than or equal to the temperature at which HTB, which is a hafnium alkoxide, is decomposed into hafnium hydroxide and isobutylene, and lower than the self-decomposition temperature of disilane, which is a silicon hydride. Specifically, it is preferable for the substrate temperature to be not lower than 350° C. and not higher than 450° C. In this manner, it is possible to form a high-quality hafnium silicate film having less carbon impurities, an enhanced insulation property and a smaller surface roughness, thereby implementing a film suitable as a gate insulating film.

In the conventional vertical batch furnace, the source gas is heated to a furnace body temperature when a source gas is introduced into the furnace. Therefore, if the furnace body temperature is set to be too high, the reaction for forming the film occurs even before the source gas is supplied to the wafer. Because of this, the furnace body temperature (i.e., wafer temperature) has to be set as low as about 280° C. However, in accordance with the present embodiment, a single-wafer film forming apparatus is employed. Therefore, by lowering a temperature in an inner space of the shower head 10 or the like until the source gas supplied from the gas supply system reaches the wafer W, it is possible to allow only the wafer W to be heated to the film forming temperature. Accordingly, it is possible to set the wafer temperature to be higher than the conventional case, e.g., higher than or equal to 350° C.

Further, in the single-wafer film forming apparatus, the temperatures of the line 41 and the shower head 10 are set to be lower than the self-decomposition temperature of HTB, which is a metal alkoxide. Therefore, HTB is prevented from being decomposed before reaching the Si wafer W, thereby ensuring that desired reactions take place in the Si wafer W.

Further, the shower head 10 is of a post-mix type, and therefore the HTB and the disilane gas are not mixed with each other in the shower head 10. Because of this, it is possible to expand the tolerance range of the shower head temperature control for suppressing the decomposition of source materials.

After the hafnium silicate film of a specific film thickness is formed as described above, the pressure in the process chamber 1 is adjusted, and the Si wafer W is unloaded from the loading/unloading port 24 by opening the gate valve 25. In this manner, the film forming process for a single wafer is completed.

Further, the present invention may be modified without being limited to the above-described embodiment. For example, although HTB has been used as the film forming source material in the above-described embodiment, other hafnium alkoxide source materials such as hafnium tetra-isopropoxide, hafnium tetra-normal butoxide can also be used as the film forming source material. Further, although the above-described embodiment has been described to be applied to the formation of the hafnium silicate film, it can also be applied to the formation of other metal silicate films. In this case, it is preferable to use an alkoxide source material containing the metal whose silicate film is to be formed. For instance, when a zirconium silicate film is formed, zirconium tetra-tertiary butoxide (ZTB) can be used. In addition, it can also be applied to a film formation of silicate of lanthanide elements. Moreover, although disilane has been used as the silicon hydride in the above-described embodiment, other silicon hydride such as monosilane can also be used.

When the metal silicate film in accordance with the present invention is formed as a gate insulating film of a semiconductor device, it is preferable to form in advance an ultra thin (thinner than or equal to 0.5 nm) base insulating film (interface film) on the substrate in order to maintain good interface conditions in relation to the silicon substrate. In this case, it is preferable to form the base insulating film by using a UV-excited O₂ radical oxidation method, which is suitable for forming an ultra thin SiO₂ film having a thickness of a few atoms. Further, in this case, the ultra thin SiO₂ film may be made to contain nitrogen by a post-nitridation process using N₂ radicals.

What is claimed is:

1. A film forming method comprising the steps of:
preparing a substrate; and
forming a metal silicate film on the substrate by a CVD process using a gas of metal alkoxide and a gas of silicon hydride,
wherein the step of forming the film is performed by setting a temperature of the substrate to be higher than or equal to a temperature at which the metal alkoxide is decomposed into metal hydroxide and a specific intermediate, and lower than a self-decomposition temperature of the silicon hydride.

2. The method of claim 1, wherein the gas of the metal alkoxide has a tertiary butoxyl radical as a ligand thereof.

3. The method of claim 2, wherein the intermediate is isobutylene.

4. The method of claim 2, wherein the metal alkoxide is HTB.

5. The method of claim 4, wherein the temperature of the substrate in the step of forming the film is higher than or equal to 350° C.

6. The method of claim 1, wherein the silicon hydride is disilane.

7. The method of claim 6, wherein the temperature of the substrate in the step of forming the film is lower than or equal to 450° C.

8. A film forming method comprising the steps of:
preparing a substrate; and
forming a hafnium silicate film on the substrate by a CVD process using a HTB gas and a disilane gas,
wherein the step of forming the film is performed by setting a temperature of the substrate to be higher than or equal to 350° C. and lower than or equal to 450° C.

9. A film forming apparatus for forming a metal silicate film on a substrate by a CVD process using a gas of metal alkoxide and a gas of silicon hydride, the apparatus comprising:
a process chamber for accommodating therein a substrate;
a heater for heating the substrate in the process chamber;
a gas supply system having a vaporizing unit for vaporizing metal alkoxide source material into a gas of metal alkoxide, the gas supply system for separately supplying the gas of the metal alkoxide and the gas of the silicon hydride to the process chamber;
a shower head for diffusing the gas of metal alkoxide and the gas of silicon hydride, each being supplied from the gas supply system, into the process chamber; and
a controller for controlling the heater such that the temperature of the substrate in the process chamber in the step of forming the film is set to be higher than or equal to a temperature at which the metal alkoxide is decomposed into metal hydroxide and a specific intermediate and lower than a self-decomposition temperature of the silicon hydride.

10. The apparatus of claim 9, wherein the metal alkoxide has a tertiary butoxyl radical as a ligand thereof.

11. The apparatus of claim 10, wherein the intermediate is isobutylene.

12. The apparatus of claim 10, wherein the metal alkoxide is HTB.

13. The apparatus of claim 12, wherein the temperature controller controls the temperature of the substrate when forming the film to be higher than or equal to 350° C.

14. The apparatus of claim 9, wherein the silicon hydride is disilane.

15. The apparatus of claim 14, wherein the temperature controller controls the temperature of the substrate when forming the film to be lower than or equal to 450° C.

16. The apparatus of claim 9, wherein the shower head is configured to separately supply the gas of metal alkoxide and the gas of silicon hydride into the process chamber.

17. A film forming apparatus for forming a hafnium silicate film on a substrate by a CVD process using an HTB gas and a disilane gas, comprising:
a process chamber for accommodating therein a substrate;
a heater for heating the substrate in the process chamber;
a gas supply system having a vaporizing unit for vaporizing an HTB liquid into an HTB gas, the gas supply system separately supplying the HTB gas and the disilane gas to the process chamber;
a shower head for diffusing the HTB gas and the disilane gas, each being supplied from the gas supply system, into the process chamber; and
a controller for controlling the heater such that the temperature of the substrate in the process chamber in the step of forming the film is set to be higher than or equal to 350° C. and lower than or equal to 450° C.

18. The apparatus of claim 17, wherein the shower head is configured to separately supply the HTB gas and the disilane gas into the process chamber.

19. A method for manufacturing a semiconductor device, comprising the steps of:
preparing a silicon substrate;
forming a silicon oxide film functioning as a base insulating film on the silicon substrate;
forming a metal silicate film functioning as a gate insulating film on the silicon oxide film by a CVD process using a gas of metal alkoxide and a gas of silicon hydride; and
forming a gate electrode on the metal silicate film,
wherein the step of forming the metal silicate film is performed by setting a temperature of the substrate to be higher than or equal to a temperature at which the metal alkoxide is decomposed into metal hydroxide and a specific intermediate and lower than a self-decomposition temperature of the silicon hydride.

20. The manufacturing method of claim 19, wherein the step of forming the silicon oxide film is performed by oxidizing a surface of the silicon substrate with UV-excited oxygen radicals.
